(19) United States
(12) Patent Application Publication
(10) Pub. No.: US 2024/0055333 A1
(43) Pub. Date: Feb. 15, 2024

(54) SEMICONDUCTOR STRUCTURE AND METHOD FOR MANUFACTURING SAME

(71) Applicant: CHANGXIN MEMORY TECHNOLOGIES, INC., Hefei City (CN)

(72) Inventors: LING-YI CHUANG, Hefei (CN); Kaimin LV, Hefei (CN)

(21) Appl. No.: 18/449,062

(22) Filed: Aug. 14, 2023

Related U.S. Application Data
(63) Continuation of application No. PCT/CN2022/117375, filed on Sep. 6, 2022.

(30) Foreign Application Priority Data
Aug. 10, 2022 (CN) 202210957711.2

(51) Int. Cl. H01L 23/495; H01L 23/31; H01L 25/065; H01L 23/00

(52) U.S. Cl. CPC H01L 23/49575; H01L 23/3128; H01L 23/4951; H01L 25/0657; H01L 24/32; H01L 24/16; H01L 24/73; H01L 2224/73253; H01L 2224/16225; H01L 2224/32227; H01L 2224/16013; H01L 2924/1435; H01L 2225/06517; H10B 80/00

(57) ABSTRACT

Provided are a semiconductor structure and a method for manufacturing the same. The semiconductor structure includes a base having power ports, a memory module located on the base and including a plurality of memory dies stacked along a first direction, in which each of the memory dies has power-supply signal wires, at least one of the memory dies has a power-supply distribution layer, the power-supply signal wires are electrically connected with the power-supply distribution layer, the power-supply distribution layer includes a first distribution layer and a second distribution layer connected with each other, a plane of the first distribution layer is perpendicular to an upper surface of the base, the second distribution layer is located on a surface of the memory die away from the base; wire bonds connected with the second distribution layer; at least one lead frame connected with the wire bonds and the power ports.

### CROSS-REFERENCE TO RELATED APPLICATIONS

This disclosure is a continuation application of International Application PCT/CN2022/117375, filed on Sep. 6, 2022, which claims priority to Chinese Patent Application No. 202210957711.2, filed on Aug. 10, 2022. The disclosures of International Application PCT/CN2022/117375 and Chinese Patent Application No. 202210957711.2 are hereby incorporated by reference in their entireties.

### BACKGROUND

In order to improve the integration of the semiconductor structure, more than one memory die may be disposed in a same package structure. HBM (High Bandwidth Memory) is a new type of memory. The technology for stacking memory dies represented by HBM expands the original one-dimensional memory layout to three-dimensional. That is, a plurality of memory dies are stacked together and packaged, thus greatly improving the density of memory dies and achieving the large capacity and the high bandwidth.

However, with the increase of stacked layers, the performance of HBM needs to be improved.

### SUMMARY

The disclosure relates to the technical field of semiconductor, in particular to a semiconductor structure and a method for manufacturing the same.

Embodiments of the disclosure provide a semiconductor structure and a method for manufacturing the same, which are at least beneficial to improving the performance of the semiconductor structure.

According to some embodiments of the disclosure, one aspect of the embodiments of the disclosure provides a semiconductor structure. The semiconductor structure includes a base having power ports, a memory module located on the base, wire bonds and at least one lead frame. The memory module includes a plurality of memory dies stacked along a first direction. The first direction is parallel to an upper surface of the base. Each of the plurality of memory dies has power-supply signal wires. At least one of the plurality of memory dies has a power-supply distribution layer. The power-supply signal wires are electrically connected with the power-supply distribution layer. The power-supply distribution layer includes a first distribution layer and a second distribution layer connected with each other. A plane of the first distribution layer is perpendicular to an upper surface of the base. The second distribution layer is located on a surface of the at least one of the plurality of memory dies away from the base. The wire bonds are connected with the second distribution layer. The at least one lead frame is connected with the wire bonds and the power ports.

According to some embodiments, another aspect of the embodiments of the disclosure also provides a method for manufacturing a semiconductor structure, which includes the following operations. A base is provided. The base has power ports. A memory module is provided. The memory module includes a plurality of memory dies stacked along a first direction. Each of the plurality of memory dies has power-supply signal wires. At least one of the plurality of memory dies has a power-supply distribution layer. The power-supply signal wires are electrically connected with the power-supply distribution layer. The power-supply distribution layer includes a first distribution layer and a second distribution layer connected with each other. A plane of the first distribution layer is perpendicular to an upper surface of the base. The second distribution layer is located on a surface of the at least one of the plurality of memory dies away from the base. The memory module is fixed on the base, and the first direction is parallel to the upper surface of the base. Wire bonds and at least one lead frame are provided. The wire bonds are connected with the second distribution layer. The at least one lead frame is connected with the wire bonds and the power ports.

### BRIEF DESCRIPTION OF THE DRAWINGS

Accompanying drawings herein, which are incorporated in and form a part of the specification, show embodiments consistent with the disclosure and serve to explain the principles of the disclosure together with the description. It is apparent that the drawings described below are only some embodiments of the disclosure, from which other drawings may be obtained without creative effort by a person of ordinary skill in the art.

FIG. 1 shows a schematic diagram of a semiconductor structure.

FIG. 2 and FIG. 5 respectively show different sectional views of semiconductor structures provided by embodiments of the disclosure.

FIG. 3, FIG. 4 and FIG. 6 respectively show schematic diagrams of different active surfaces of memory dies provided by embodiments of the disclosure.

FIG. 7 shows a top view of a lead frame, wire bonds and a power-supply distribution layer provided by an embodiment of the disclosure.

FIG. 8 and FIG. 9 show schematic structural diagrams corresponding to different operations of a method for manufacturing a semiconductor structure provided by another embodiment of the disclosure.

### DETAILED DESCRIPTION

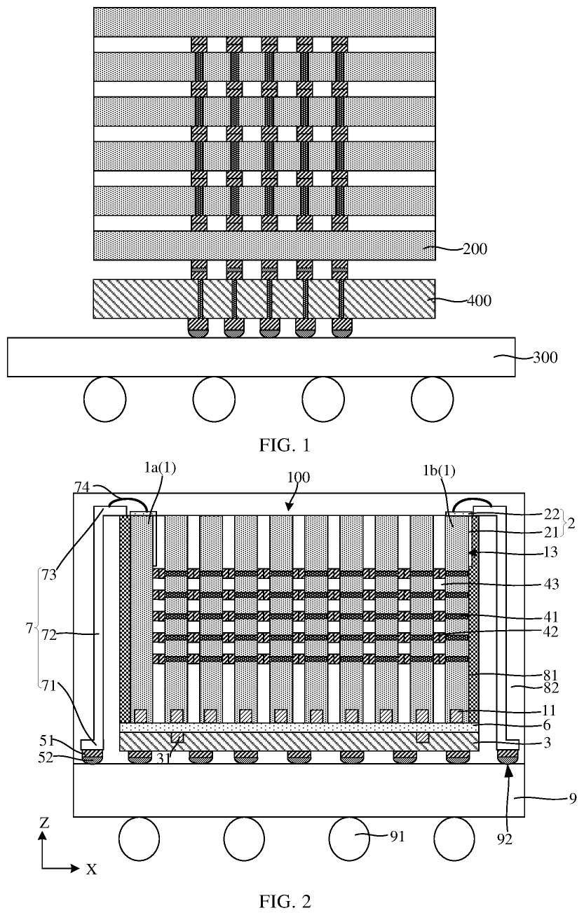

Referring to FIG. 1, HBM adopts a parallel stacking way. That is, front surfaces of a plurality of memory dies 200 are parallel to an upper surface of a base 300. In other words, an arrangement direction of the plurality of memory dies 200 is perpendicular to the upper surface of the base 300. When the number of stacked layers is large, a communication distance between a uppermost memory die 200 and a logical die 400 and a communication distance between a lowest memory die 200 and the logical die 400 are quite different, which leads to communication delays between different memory dies 200 and the logical die 400 are quite different, thus affecting the operation speed of a product. In addition, the power supply way of a semiconductor structure may also affect its performance.

Embodiments of the disclosure provide a semiconductor structure. A plurality of memory dies are stacked along a direction parallel to an upper surface of the base. That is, an arrangement direction of the plurality of memory dies is parallel to the upper surface of the base, so communication distances of the plurality of memory dies are same, which is beneficial to unify communication delays and improve the operation speed. In addition, the power-supply distribution layers in the memory dies can change the layout of power-supply signal wires and lead the power-supply signal wires out of the memory dies, that is, the reliability of power supply can be improved by wired power supply. In addition, the wire bonds make connection between the lead frames and the memory module more flexible, and the lead frames can standardize the layout of power supply paths, thus ensuring stability of power supply.

Embodiments of the disclosure will be described in detail below with reference to the accompanying drawings. However, those skilled in the art will understand that, numerous technical details have been set forth in various embodiments of the disclosure, in order to make the reader better understand the disclosure. However, even without these technical details and various changes and modifications based on the following embodiments, the technical solutions claimed in the disclosure can be implemented.

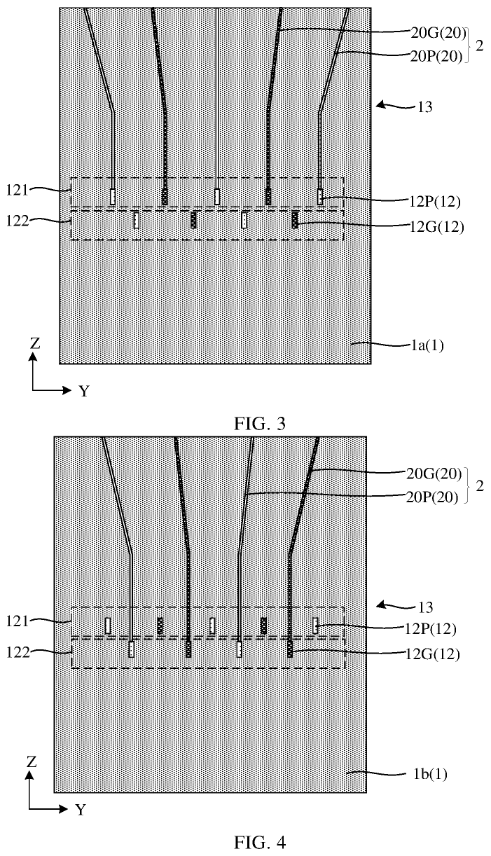

As shown in FIG. 2 to FIG. 7, embodiments of the disclosure provide a semiconductor structure, which includes a base 9 having power ports 92, a memory module 100 located on the base 9, wire bonds 74 and at least one lead frame 7. The memory module 100 includes a plurality of memory dies 1 stacked along a first direction X parallel to an upper surface of the base 9. Each of the plurality of memory dies 1 has power-supply signal wires 12. At least one of the plurality of memory dies 1 has a power-supply distribution layer 2. The power-supply signal wires 12 are electrically connected with the power-supply distribution layer 2. The power-supply distribution layer 2 includes a first distribution layer 21 and a second distribution layer 2 connected with each other. A plane of the first distribution layer 21 is perpendicular to the upper surface of base 9. The second distribution layer 22 is located on a surface of the plurality of memory dies 1 away from the base 9. The wire bonds 74 are connected with the second distribution layer 22. The at least one lead frame 7 is connected with the wire bonds 74 and the power ports 92.

Such design includes at least the following effects.

First, the power-supply distribution layer 2 can lead the power-supply signal wires 12 out, so as to provide wired power supply to the memory dies 1, thus improving the stability of power supply. Specifically, surfaces of each of the memory dies 1 includes a front surface and a back surface opposite to each other, and side surfaces connecting the front surface and the back surface. The area of the front surface or the back surface is larger than the area of one of the side surfaces. A plane where the first distribution layer 21 is located is perpendicular to the upper surface of the base 9. In other words, the first distribution layer 21 may be located on the front surface or the back surface of the memory die 1 for connecting the power-supply signal wires 12. The second distribution layer 22 leads the first distribution layer 21 out to the side surface of the memory die 1. That is, the second distribution layer 22 may serves as pads connecting the first distribution layer 21 and the wire bonds 74, so as to increase soldering areas, reduce soldering difficulty and reduce contact resistance between the power-supply distribution layer 2 and the wire bonds 74.

Second, the wire bonds 74 and the lead frame 7 can form wired power supply paths between the base 9 and the memory dies 1. The lead frame 7 has high strength and is not easy to deform, so that it can standardize directions of the wired power supply paths. The wire bonds 74 are easy to bend, which can improve the flexibility of connecting the lead frame 7 and the power-supply distribution layer 2.

Third, the plurality of memory dies 1 are stacked along the first direction X, that is, the arrangement direction of the plurality of memory dies 1 is parallel to the base 9. Thus, side surfaces of the memory dies 1 face the base 9, and since the area of the side surfaces of the memory dies 1 is small, an area of the upper surface of the base 9 occupied is small, which is beneficial to increase the stacked number of the memory dies 1.

The semiconductor structure will be described in detail with reference to the accompany drawings.

First, it is to be noted that, the semiconductor structure has a first direction X, a second direction Y, and a third direction Z. The first direction X is a stacked direction of the memory dies 1. The second direction Y is perpendicular to the first direction X and is parallel to an upper surface of the logic die 3. The third direction Z is perpendicular to the upper surface of the logic die 3.

Referring to FIG. 2 and FIG. 5, a plurality of memory die 1 may be stacked in a manner of hybrid bonding. For example, dielectric layers 43 may also be provided on surfaces on each of the memory dies 1. Each of the dielectric layers 43 may be connected with the adjacent memory dies 1 by action force such as molecular forces. In addition, bonding parts 42 may also be provided on the surfaces on each of the memory dies 1. Each of the bonding parts 42 is connected with the adjacent memory dies 1 by bonding under heating conditions. In other words, the dielectric layers 43 are of an insulating material and can play an isolation role. The bonding parts 42 are of a conductive material and can play a role of electrical connection. In addition, the dielectric layers 43 also expose an end surface of the first distribution layer 21 facing away from the logic die 3, and cover another surface of the first distribution layer 21 except the end surface.

The memory dies 1 may be dies such as DRAM (Dynamic Random Access Memory) or SRAM (Static Random-Access Memory). In some embodiments, the adjacent memory dies 1 may be stacked in a front-to-back way, which is beneficial to unify bonding operations of the memory dies 1 and makes the manufacturing process simpler. In some embodiments, the adjacent memory dies 1 may also be stacked in a front-to-front or back-to-back way. In an embodiment, the front surface of each of the memory dies 1 may be understood as an active surface 13, and the back surface may be understood as a non-active surface opposite to the active surface.

Referring to FIG. 2 to FIG. 6, the first distribution layer 21 may be located on the front surface of the corresponding memory die 1, i.e. extending along the active surface 13 of the corresponding memory die 1. Therefore, after the components in the memory die 1 are manufactured, the first distribution layer 21 may be manufactured by an original back end of line, and the process is simpler. In addition, the first distribution layer 21 may extend only at an edge position of the side near the active surface 13 of the memory die 1 without covering the entire active surface 13 of the memory die 1. Therefore, a contact area between the first distribution layer 21 and the memory die 1 is small, which reduces an influence of heat generated by the first distribution layer 21 on the memory die 1.

Referring to FIG. 2 and FIG. 5, a ratio of a width of the second distribution layer 22 along the first direction X to a width of the corresponding memory die 1 along the first direction X is 0.8 to 2. For example, the width of the second distribution layer 22 along the first direction X is equal to the width of the corresponding memory die 1. In this way, a sufficient soldering area between the wire bonds 74 and the power-supply distribution layer 2 can be ensured, and materials can be saved and production costs can be reduced.

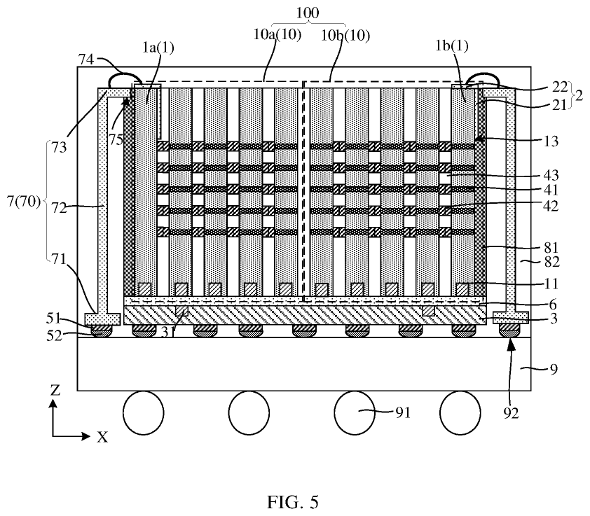

Referring to FIGS. 3-4 and FIG. 6, each of the memory dies 1 has a plurality of power-supply signal wires 12. One end of each of the power-supply signal wires 12 is led out on the active surface 13 for connection to the power-supply distribution layer 2. The different power-supply signal wires 12 may provide different voltage signals such as digital signals or analog signals for the components within the memory die 1. The power-supply signal wires 12 may be grounding signal wires 12G or power signal wires 12P. The different grounding signal wires 12G have different voltage signals, and the different power signal wires 12P have different voltage signals.

Referring further to FIGS. 3-4 and FIG. 6, each of the power-supply distribution layers 2 includes a plurality of power-supply wires 20 arranged at intervals. Each of the power-supply wires 20 is electrically connected with a corresponding one of the power-supply signal wires 12. The different power-supply signal wires 12 have different voltage signals, and correspondingly, the different power-supply wires 20 have different voltage signals. The power-supply distribution layer 2 includes grounding wires 20G and power wires 20P. Each of the grounding wires 20G is electrically connected with a corresponding one of the grounding signal wires 12G, and each of the power wires 20P is electrically connected with a corresponding one of the power signal wires 12P.

If a memory die 1 has its own power-supply distribution layer 2, at least part of the power-supply signal wires 12 of the memory die 1 may be directly connected with its own power-supply distribution layer 2. That is, the part of the power-supply signal wires may be led out through its own power-supply distribution layer 2. If a memory die 1 does not have its own power-supply distribution layer 2, the power-supply signal wires 12 of the memory die 1 may be led out through the power-supply distribution layer 2 of another memory die 1. In other words, the memory die 1 may establish an electrical connection relationship with another memory die 1 by conductive vias 41 and bonding parts 42, thereby electrically connecting its own power-supply signal wires 12 with the power-supply signal wires 12 of the another memory die 1, and further with the power-supply distribution layer 2 of the another memory die 1.

The position and quantity relationships between the memory dies 1 and the power-supply distribution layers 2 will be described in detail below.

Referring to FIG. 2 and FIG. 5, at least one of the memory dies 1 at two outermost sides of the memory module 100 has a power-supply distribution layer 2. Each of the memory dies 1 has conductive vias 41. The conductive vias 41 are electrically connected with the power-supply signal wires 12. Bonding parts 42 are disposed between two adjacent ones of the memory dies 1, and the bonding parts 42 are connected with the conductive vias 41. The power-supply signal wires 12 of the plurality of memory dies 1 are electrically connected through the conductive vias 41 and the bonding parts 42.

Compared with disposing the power-supply distribution layer 2 on a memory die 1 in the middle of the memory module 100, disposing the power-supply distribution layer 2 on a memory die 1 at the outermost side of the memory module 100 is beneficial to reduce the distance between the power-supply distribution layer 2 and the lead frame 7, thus shortening the lengths of the wire bonds 74 to reduce power consumption and reducing the height of the whole package along the third direction Z.

In some embodiments, the two memory dies 1 at the two outermost sides of the memory module 100 have the power-supply distribution layers 2 respectively. The semiconductor structure includes two groups of the lead frames 7, and the two groups of the lead frames 7 are respectively close to the two memory dies 1 at the two outermost front and tail sides, and are connected with two power-supply distribution layers 2 respectively.

That is, the power-supply signal wires 12 may be led out from the two outermost sides of the memory module 100. Compared with leading the power-supply signal wires 12 out from one side of the memory module 100, leading the power-supply signal wires 12 out from both sides can provide more leading out positions, which is beneficial to reduce process difficulty and improve the reliability of power supply. In other embodiments, the power-supply signal wires 12 may be led out from one side of the memory module 100.

Specifically, referring to FIG. 2 to FIG. 4, FIG. 3 and FIG. 4 are schematic diagrams of the active surfaces 13 of the memory dies 1 at the two outermost sides shown in FIG. 2 respectively. Each of the memory dies 1 has a first power-supply signal wire group 121 and a second power-supply signal wire group 122. The first power-supply signal wire group 121 and the second power-supply signal wire group 122 each include a plurality of power-supply signal wires 12. All of the first power-supply signal wire groups 121 are electrically connected with one power-supply distribution layer 2, and all of the second power-supply signal wire groups 122 are electrically connected with another power-supply distribution layer 2.

For example, the two memory dies 1 at the two outermost sides are the first memory die 1a and the second memory die 1b, respectively. Referring to FIG. 2 and FIG. 3, the first power-supply signal wire group 121 of the first memory die 1a is directly connected with the power-supply distribution layer 2 on the surface of the first memory die 1a, and the first power-supply signal wire groups 121 of the memory dies 1 other than the first memory die 1a are electrically connected with the first power supply signal group 121 of the first memory die 1a through the bonding parts 42 and the conductive vias 41, so that all of the first power-supply signal wire groups 121 can be led out from the power-supply distribution layer 2 on the surface of the first memory die 1a. Similarly, referring to FIG. 2 and FIG. 4, the second power-supply signal wire group 122 of the second memory die 1b is directly connected with the power-supply distribution layer 2 on the surface of the second memory die 1b, and the second power-supply signal wire groups 122 of the memory dies 1 other than the second memory die 1b are electrically connected with the second power supply signal group 122 of the second memory die 1b through the bonding parts 42 and the conductive vias 41, so that all of the second power-supply signal wire groups 122 can be led out from the power-supply distribution layer 2 on the surface of the second memory die 1b.

That is, the first signal line groups 121 and the second signal line groups 122 are respectively led out from both sides of the memory module 100, which is beneficial to provide more sufficient connection positions for the wire bonds 74, so as to increase the distance between the adjacent wire bonds 74 and avoid wrong electrical connection.

Referring to FIG. 5 to FIG. 6, FIG. 6 is a schematic diagram of the active surfaces 13 of the memory dies 1 at the two outermost sides shown in FIG. 5. The memory module 100 includes two die set 10 arranged along the first direction X, and each of the die sets 10 includes a plurality of memory dies 1. Power-supply signal wires 12 of a same die set 10 are electrically connected with their nearest power-supply distribution layer 2.

For example, the memory module 100 includes a first die set 10a and a second die set 10b. All of the power-supply signal wires 12 of the first memory die 1a may be electrically connected directly with the power-supply distribution layer 2 on the surface of the first memory die 1a. The power-supply signal wires 12 of other memory dies 1 within the first die set 10a may be electrically connected with the power-supply signal wires 12 of the first memory die 1a through the bonding parts 42 and the conductive vias 41, so that all of the power-supply signal wires 12 of the first die set 10a can be led out from the power-supply distribution layer 2 on the surface of the first memory die 1a. Similarly, all of the power-supply signal wires 12 of the second memory die 1b may be electrically connected directly with the power-supply distribution layer 2 on the surface of the second memory die 1b. The power-supply signal wires 12 of other memory dies 1 within the second die set 10b may be electrically connected with the power-supply signal wires 12 of the second memory die 1b through the bonding parts 42 and the conductive vias 41, so that all of the power-supply signal wires 12 of the second die set 10b can be led out from the power-supply distribution layer 2 on the surface of the second memory die 1b. The power-supply signal wires 12 of the two die sets 10 are led out separately, which is beneficial to improve the stability and reliability of power supply.

The lead frames 7 will be described in detail below.

Referring to FIG. 2 and FIG. 5, the at least one lead frame 7 and the memory module 100 are arranged along the first direction X. That is, the at least one lead frame 7 is disposed opposite to a corresponding memory die 1 at the outermost sides of the memory module 100. In this way, it is beneficial to reduce the distances between the at least one lead frame 7 and the power-supply distribution layer 2, so as to shorten the lengths of the wire bonds 74.

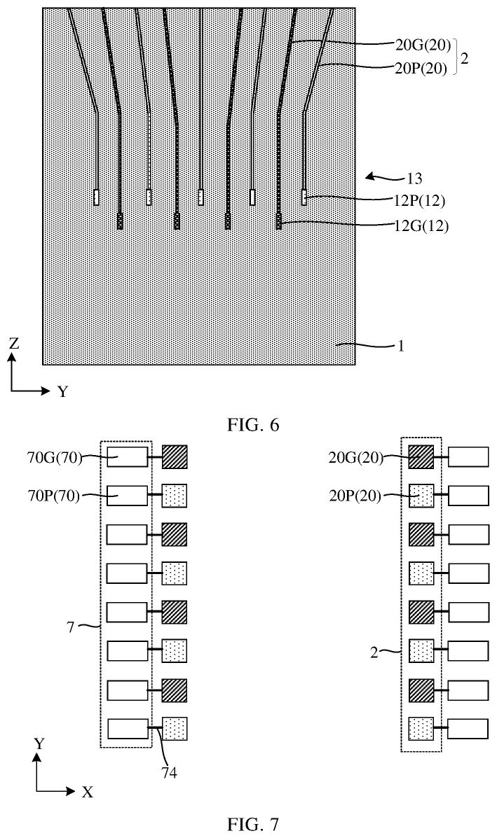

Referring to FIG. 7, FIG. 7 is a top view of the lead frames 7, the wire bonds 74 and the power-supply distribution layers 2. Since each of the power-supply distribution layers 2 includes a plurality of power-supply wires 20 arranged at intervals along the second direction Y, and accordingly, each of the lead frames 7 include a plurality of frame strips 70 arranged at intervals along the second direction Y. Each of the frame strips 70 and a corresponding power-supply wire 20 connected with the frame strip 70 have a same voltage signal. For example, each of the power-supply wires 20 may be disposed face-to-face with a corresponding one of the frame strips 70 along the first direction X, thereby facilitating the arrangement of the wire bonds 74.

The frame strips 70 are power frame strips 70P or grounding frame strips 70G. The power frame strips 70P are electrically connected with the power wires 20P, and the grounding frame strips 70G are electrically connected with the grounding wires 20G. The power frame strips 70P and the grounding frame strips 70G are alternately arranged along the second direction Y. That is, end surfaces of the power-supply wires 20 away from the base 9 may also be alternately arranged along the second direction Y. Because of great difference between the power supply signals and the grounding signals, the alternating arrangement of the two is beneficial to reduce electromagnetic interference between the adjacent frame strips 70.

Referring to FIG. 2 and FIG. 5, each of the lead frames 7 includes a supporting frame 71 and a body frame 72 connected with each other. The supporting frame 71 is soldered to the upper surface of base 9. The body frame 72 extends along the direction perpendicular to the upper surface of the base 9. That is, the body frame 72 extends along the third direction Z. A width of the supporting frame 71 along the first direction X is greater than a width of the body frame 72 along the first direction X.

That is, the supporting frame 71 extends along a direction parallel to the upper surface of the base 9, which is beneficial to increase a soldering area between the lead frame 7 and the base 9, so as to enhance the soldering firmness. For example, a soldering bump 51 and a solder layer 52 are provided between the supporting frame 71 and the base 9.

Referring to FIG. 2, in some embodiments, an end of each of the supporting frames 71 is connected with an end of a corresponding one of the body frames 72. That is, a strip-shaped conductive material is bent into two sections to serve as the supporting frame 71 and the body frame 72 respectively, and the production process is simpler.

Referring to FIG. 5, in other embodiments, an orthographic projection of each of the body frames 72 on the upper surface of the base 9 is located at a central position in an orthographic projection of each of the supporting frames 71 on the upper surface of the base 9. That is, the body frame 72 and the supporting frame 71 may form an inverted T-shape, and the stability of the lead frame 7 is better.

Referring further to FIG. 2 and FIG. 5, each of the lead frames 7 further includes a soldering frame 73 having a width along the first direction X larger than the width of the body frame 72 along the first direction X. The soldering frame 73 and a leading wire 74 are soldered. An end of the body frame 72 away from the supporting frame 71 is connected with the soldering frame 73. That is, the soldering frame 73 extends along the direction parallel to the upper surface of the base 9, which is beneficial to increase the soldering area between the wire bonds 74 and the lead frame 7, so as to facilitate soldering.

In other embodiments, each of the lead frames 7 may also include only a body frame 72, without a soldering frame 73 and a supporting frame 71. That is, the opposite ends of the body frame 72 are soldered to the upper surface of base 9 and the wire bonds 74, respectively.

It is to be noted that since each of the lead frames 7 include a plurality of the frame strips 70 arranged at intervals. In other words, each of the plurality of frame strips 70 may include a body frame 72, a soldering frame 73, and a supporting frame 71.

Referring further to FIG. 2 and FIG. 5, the semiconductor structure further includes a first sealing layer 81 that surrounds the memory module 100 and exposes a surface of the memory module 100 away from the base 9. The first sealing layer 81 can protect the memory module 100 from external environment, such as external moisture, solvent, and from thermal shock and mechanical vibration when the semiconductor structure is installed.

For example, the first sealing layer 81 is in contact with the soldering frames 73. In this way, the first sealing layer 81 can support the soldering frames 73, thereby improving stability of the structure. In addition, it is also beneficial to reduce the distance between the soldering frames 73 and the memory module 100, thus reducing the lengths of the wire bonds 74.

For example, referring to FIG. 2, the bottom surface of the soldering frame 73 may be located on a top surface of the first sealing layer 81. In other embodiments, referring to FIG. 5, a side of the first sealing layer 81 away from the base 9 has grooves 75, and the soldering frames 73 are clamped within the grooves 75. For example, the soldering frames 73 are arranged at opposite sides along the second direction Y and may be in contact with sidewalls of the grooves 75, and bottom surfaces of the soldering frames 73 may be in contact with bottom surfaces of the grooves 75. That is, the first sealing layer 81 can serve to fix the soldering frames 73, and thus to improve stability of the lead frames 7.

Referring to FIG. 2 and FIG. 5, the semiconductor structure further includes a second sealing layer 82 covering the memory module 100, the wire bonds 74, the lead frames 7, the second distribution layers 22, and the first sealing layers 81. The second sealing layer 82 can improve protection and isolation effect, so as to ensure performance of the semiconductor structure.

In an embodiment, a material of the first sealing layer 81 and a material of the second sealing layer 82 may be same. For example, both the first sealing layer 81 and the second sealing layer 82 may be epoxy resin.

In an embodiment, the material of the first sealing layer 81 and the material of the second sealing layer 82 may be different. For example, the thermal conductivity of the second sealing layer 82 is higher than that of the first sealing layer 81. By this arrangement, heat introduced into the second sealing layer 82 through the lead frames 7 can be transferred to the external environment more quickly, so that adverse effect of high temperature environment on the memory module 100 is reduced.

Referring to FIG. 2 and FIG. 5, the semiconductor structure further includes a logic die 3 located between the upper surface of the base 9 and the memory module 100. First wireless communication parts 31 are provided in the logical die 3. Second wireless communication parts 11 are provided in the memory dies 1. The second wireless communication parts 11 communicate with the first wireless communication parts 31 wirelessly.

Since the distances between the plurality of memory dies 1 and the logical die 3 are same, delays of wireless communication between the plurality of memory dies 1 and the logical die 3 is consistent. In some embodiments, the second wireless communication parts 11 are located on sides of the memory dies 1 facing the logic die 3. Therefore, the distances between the first wireless communication parts 31 and the second wireless communication parts 11 can be reduced, thereby improving the quality of the wireless communication.

It is to be noted that, if the arrangement direction of the plurality of the memory dies 1 is perpendicular to an upper surface of the logical die 3, the communication delays between different layers of the memory dies 1 and the logical die 3 are quite different. In addition, as the number of layers increases, the number of through silicon vias (TSV) used for communication will increase proportionally, thus sacrificing wafer area. In the embodiments of the disclosure, the stacking direction and communication way of the memory dies 1 are changed, which is beneficial to improve the communication quality and save the wafer area.

Referring further to FIG. 2 and FIG. 5, the side surfaces of the memory dies 1 are arranged towards the logical die 3, and the area of each of the side surfaces is small. By adopting the wireless communication way, there is no need to dispose wired communication parts between the memory dies 1 and the logic die 3, which can reduce process difficulty and provide sufficient space for the connection structures between the memory dies 1 and the logic die 3, so as to improve their structural strength. In addition, a lower side of the memory module 100 is used for performing the wireless communication, and an upper side of the memory module 100 is used for arranging the wired power supply paths, so that electromagnetic interference caused by currents in the wired power supply paths to coils in the wireless communication parts can be reduced and signal loss can be avoided.

In some embodiments, an adhesive layer 6 is further provided between the memory module 100 and the logic die 3. That is, the memory module 100 and the logic die 3 are connected together by gluing to form a memory particle. For example, the adhesive layer 6 may be a die attach film (DAF). An adhering process is simple and can save cost. In addition, metal ions may be doped in the adhesive layer 6 to improve the heat dissipation effect for the memory module 100 and the logic die 3. In other embodiments, a soldering layer (not shown) may be provided between the memory module 100 and the logic die 3. That is, the memory module 100 and the logic die 3 are connected together by soldering.

That is, leading the power-supply signal wires 12 out from the top of the memory module 100 can leave enough space at the bottom of the memory module 100 to connect the logical die 3, thus improving the structural strength.

Referring further to FIG. 2 and FIG. 5, soldering bumps 51 and solder layers 52 is further provided between the logic die 3 and the base 9. That is, the logic die 3 is soldered to the base 9 by flip-chip soldering. In this way, the base 9 can supply power and exchange signals to the logic die 3 in a wired way, and the reliability of the wired way is high.

To sum up, in the embodiments of the disclosure, a connection way of the wire bonds 74 is adopted at upper ends of the lead frames 7, which makes the connection way between the lead frames 7 and the memory module 100 more flexible. Moreover, a connection way of the soldering bumps 51 is adopted at lower ends of the lead frames 7, which makes connection stability between the lead frames 7 and the base 9 higher. The two connection ways are matched to make the wired power supply paths flexible and stable.

As shown in FIG. 8 to FIG. 9 and FIG. 2, another embodiment of the disclosure provides a method for manufacturing a semiconductor structure. The semiconductor structure provided by foregoing embodiments may be manufactured by the method. For a detailed description of the semiconductor structure, reference is made to the foregoing embodiments.

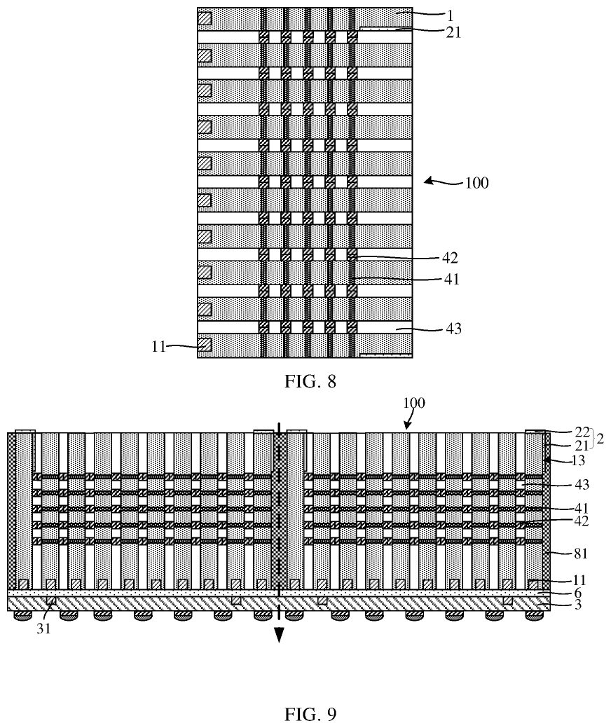

Specifically, referring to FIG. 8, a memory module 100 is provided. The memory module 100 includes a plurality of memory dies 1 stacked along a first direction X. Each of the memory dies 1 has power-supply signal wires 12. At least one of the plurality of memory dies 1 has a power-supply distribution layer 2. The power-supply signal wires 12 are electrically connected with the power-supply distribution layer 2. The power-supply distribution layer 2 includes a first distribution layer 21 and a second distribution layer 22. A plane of the first distribution layer 21 is perpendicular to the upper surface of base 9. The second distribution layer 22 is located on a surface of the memory dies 1 away from the base 9.

Specifically, the plurality of memory dies 1 are provided. A first distribution layer 21 is formed on at least one of the plurality of memory dies 1. After the first distribution layer 21 is formed, the plurality of memory dies 1 are stacked and bonded. For example, the power-supply signal wires 12 of each layer of the memory dies 1 are led out to a top memory die 1 and a bottom memory die 1 through conductive vias 41 and bonding parts 42, and then led to edges of the memory dies 1 by processing the power-supply distribution layers 2 on the top memory die 1 and the bottom memory die 1. It is to be noted that, during the bonding process, the memory dies 1 are placed horizontally.

Referring to FIG. 9, a first molding process is performed on the memory module 100 to form a first sealing layer 81 surrounding the memory module 100. The first sealing layer 81 also exposes surfaces of the memory dies 1 and the first distribution layer 21 away from the base 9. After the first molding process, a second distribution layer 22 is formed on the surface of the corresponding memory die 1 away from the base 9.

For example, the memory module 100 is rotated by 90°, so that each of the memory dies 1 is perpendicular to the logic die 3. The memory dies 1 and the logic die 3 are fixed through the DAF film. A plurality of memory modules 100 are reconstructed through the first molding process to form a reconstructed wafer. The second distribution layers 22 are deposited on a top surface of the reconstructed wafer as pads by a redistribution process.

Referring to FIG. 2, a base 9 is provided. The base 9 is provided with power ports 92. The memory module 100 is fixed on the base 9. The first direction X is parallel to an upper surface of the base 9. Wire bonds 74 and at least one lead frame 7 are provided. The wire bonds 74 are connected with the second distribution layer 22. The at least one lead frame 7 is connected with the wire bonds 74 and the power ports 92.

Specifically, the reconstructed wafer is scribed to form memory particles, each of which includes a memory module 100 and a logic die 3. The memory particles are soldered to the base 9 on which the lead frame 7 has been soldered in advance by flip-chip soldering. The power-supply wires 20 are respectively connected with the corresponding lead frame strips 70 through the wire bonds 74, so as to achieve the connection of power supply signals between the memory dies 1 and the base 9. Thereafter, a second sealing layer 82 covering the structures of the memory module 100, the wire bonds 74, the lead frames 7 and the like is formed by a second molding process.

It is to be noted that a reason for adopting the two molding processes is that: the first molding process may connect a plurality of memory modules 100 together, so that the second distribution layers 22 may be formed on the plurality of memory modules 100 synchronously, which is beneficial to reduce process operations. In addition, the volume of a single memory module 100 is small, and the total volume of the plurality of memory modules 100 after being connected together becomes larger, which have higher stability and are not easy to topple. In addition, the first sealing layer 81 formed by the first molding process can protect and fix the memory modules 100 in subsequent operations of forming the second distribution layers 22 and flip-chip soldering, so as to prevent the memory modules 100 from collapsing or being damaged, thereby being beneficial to ensuring the performance of the memory modules 100. In addition, the two molding processes in order can improve sealing effect. The bottom surface of the base 9 may have solder balls 91 to solder the base 9 to a peripheral circuit board.

To sum up, a memory particle are formed by vertically stacking a plurality of memory dies 1 and the logical die 3, and then the power-supply distribution layers 2 are led out to the base 9 by the lead frames 7 for packaging. Signal communication between the memory dies 1 and the logic die 3 is implemented wirelessly, which can effectively solve communication difficulties caused by the increase of layers of the memory dies 1 stacked in parallel.

In the description of the specification, descriptions referring to the terms “some embodiments” “other embodiments” “for example” or the like mean that specific features, structures, materials, or characteristics described in conjunction with the embodiments or examples are included in at least one embodiment or example in the disclosure. In this specification, schematic expressions of the above terms do not necessarily refer to a same embodiment or example. Further, the specific features, structures, materials, or characteristics described may be combined in a suitable manner in any one or more embodiments or examples. In addition, those skilled in the art may combine and compose different embodiments or examples and the features of different embodiments or examples described in the specification without contradicting each other.

Although the embodiments of the disclosure have been shown and described above, it is to be understood that the above embodiments are exemplary and should not be understood as limitations of the disclosure. Those skilled in the art can make changes, modifications, substitutions and variants to the above embodiments within the scope of the disclosure, so any changes or modifications made according to the claims and the specification of the disclosure should be within the scope of the disclosure.

1. A semiconductor structure, comprising:
a base, having power ports;
a memory module located on the base, the memory module comprising a plurality of memory dies stacked along a first direction, the first direction being parallel to an upper surface of the base, wherein,
each of the plurality of memory dies has power-supply signal wires, at least one of the plurality of memory dies has a power-supply distribution layer, and the power-supply signal wires are electrically connected with the power-supply distribution layer,
the power-supply distribution layer comprises a first distribution layer and a second distribution layer connected with each other, a plane of the first distribution layer is perpendicular to the upper surface of the base, and the second distribution layer is located on a surface of the at least one of the plurality of memory dies away from the base;
wire bonds, connected with the second distribution layer; and
at least one lead frame, connected with the wire bonds and the power ports.

2. The semiconductor structure of claim 1, wherein the at least one lead frame and the memory module are arranged along the first direction.

3. The semiconductor structure of claim 2, wherein at least one of the memory dies at two outermost sides of the memory module has the power-supply distribution layer;
each of the plurality of memory dies is provided with conductive vias, and the conductive vias are electrically connected with the power-supply signal wires; bonding parts are disposed between two adjacent ones of the plurality of memory dies, and the bonding parts are connected with the conductive vias; and
the power-supply signal wires of the plurality of the memory dies are electrically connected with each other by the bonding parts and the conductive vias.

4. The semiconductor structure of claim 3, wherein the two memory dies at the two outermost sides of the memory module have the power-supply distribution layers respectively; and
the semiconductor structure comprises two groups of the lead frames, and the two groups of the lead frames are respectively close to the two memory dies at the two outermost sides and are respectively connected with two power-supply distribution layers.

5. The semiconductor structure of claim 4, wherein
each of the plurality of memory dies has a first power-supply signal wire group and a second power-supply signal wire group, the first power-supply signal wire group and the second power-supply signal wire group each comprise a plurality of the power-supply signal wires; and
all of the first power-supply signal wire groups are electrically connected with one of the two power-supply distribution layers; all of the second power-supply signal wire groups are electrically connected to another one of the two power-supply distribution layers.

6. The semiconductor structure of claim 4, wherein
the memory module comprises two die sets arranged along the first direction, and each of the two die sets comprises a plurality of the memory dies; and
the power-supply signal wires in the same die set are electrically connected with a nearest one of the two power-supply distribution layers.

7. The semiconductor structure of claim 1, wherein the at least one lead frame comprises a plurality of frame strips arranged at intervals, and each of the plurality of frame strips is a power frame strip or a grounding frame strip, the power frame strips and the grounding frame strips are alternately arranged along a second direction, and the second direction is parallel to the upper surface of the base and perpendicular to the first direction;
each of the power-supply distribution layers comprises a plurality of power wires and a plurality of grounding wires, and the power-supply signal wires comprise power signal wires and grounding signal wires; and
the plurality of power wires are electrically connected with the power frame strips and the power signal wires, and the plurality of grounding wires are electrically connected with the grounding frame strips and the grounding signal wires.

8. The semiconductor structure of claim 1, wherein
the at least one lead frame comprises a plurality of frame strips arranged at intervals, and each of the plurality of frame strips comprises a supporting frame and a body frame connected with each other, wherein,
the supporting frame is soldered on the upper surface of the base;
the body frame extends along a direction perpendicular to the upper surface of the base; and
a width of the supporting frame along the first direction is larger than a width of the body frame along the first direction.

9. The semiconductor structure of claim 8, wherein,
the frame strip further comprises a soldering frame, which has a width along the first direction larger than the width of the body frame along the first direction;
the soldering frame is soldered with a corresponding one of the wire bonds; and
one end of the body frame far away from the supporting frame is connected with the soldering frame.

10. The semiconductor structure of claim 8, wherein an orthographic projection of the body frame on the upper surface of the base is located at a central position in an orthographic projection of the supporting frame on the upper surface of the base.

11. The semiconductor structure of claim 9, further comprising:
a first sealing layer surrounding the memory module and exposing a surface of the memory module away from the base;
wherein the first sealing layer is in contact with the soldering frame.

12. The semiconductor structure of claim 11, wherein a side of the first sealing layer away from the base has grooves, and the soldering frame is clamped within a corresponding one of the grooves.

13. The semiconductor structure of claim 1, further comprising: a logical die located between the upper surface of the base and the memory module, wherein,
the logical die is provided with first wireless communication parts; the plurality of memory dies are provided with second wireless communication parts; and the second wireless communication parts communicate with the first wireless communication parts wirelessly.

14. The semiconductor structure of claim 13, further comprising an adhesive layer or a soldering layer between the memory module and the logic die.

15. The semiconductor structure of claim 1, a ratio of a width of the second distribution layer along the first direction to a width of the at least one of the plurality of memory dies along the first direction is 0.8 to 2.

16. A method for manufacturing a semiconductor structure, comprising:
providing a base, the base having power ports; and
providing a memory module, the memory module comprising a plurality of memory dies stacked along a first direction, wherein,
each of the plurality of memory dies has power-supply signal wires, at least one of the plurality of memory dies has a power-supply distribution layer, and the power-supply signal wires are electrically connected with the power-supply distribution layer; the power-supply distribution layer comprises a first distribution layer and a second distribution layer connected with each other, a plane of the first distribution layer is perpendicular to an upper surface of the base, the second distribution layer is located on a surface of the memory die away from the base;
fixing the memory module on the base, the first direction being parallel to the upper surface of the base; and
providing wire bonds and at least one lead frame, the wire bonds being connected with the second distribution layer, and connecting the at least one lead frame with the wire bonds and the power ports.

17. The method for manufacturing a semiconductor structure of claim 16, wherein providing a memory module comprises:
providing the plurality of memory dies;
forming the first distribution layer on at least one of the plurality of memory dies; and
stacking and bonding the plurality of memory dies after forming the first distribution layer;
before fixing the memory module on the base, the method further comprises:
performing a first molding process on the memory module to form a first sealing layer surrounding the memory module, the first sealing layer exposing surfaces of the plurality of memory dies and the first distribution layer away from the base; and
forming the second distribution layer on the surface of the at least one of the plurality of memory dies away from the base after the first molding process.
